(19) United States
(12) Patent Application Publication
(10) Pub. No.: US 2008/0318359 A1
(43) Pub. Date: Dec. 25, 2008

(54) METHOD OF MANUFACTURING SILICON CARBIDE SEMICONDUCTOR SUBSTRATE

(75) Inventors: Yoshiyuki Yonezawa, Matsumoto City (JP); Takeshi Tawara, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/139,446

(22) Filed: Jun. 13, 2008

(30) Foreign Application Priority Data
Jun. 18, 2007 (JP) 2007-159643

(51) Int. Cl. H01L 21/205

(52) U.S. Cl. 438/105; 257/E21.105

(57) ABSTRACT

A method of manufacturing a silicon carbide semiconductor substrate is disclosed in which the density of basal plane dislocations (BPDs) in particular is reduced in an SiC crystal substrate. Irregularities in the surface of the substrate due to this reduction also can be flattened. A method of manufacturing a silicon carbide semiconductor substrate is disclosed in which, prior to forming an epitaxial growth layer on a silicon carbide substrate with an off-axis angle of 1° to 8°, parallel line-shape irregularities, which have an irregularity cross-sectional aspect ratio equal to or greater than the tangent of the off-axis angle of the silicon carbide substrate, are formed in the substrate surface. The irregularites have a height between 0.25 μm and 5 μm.

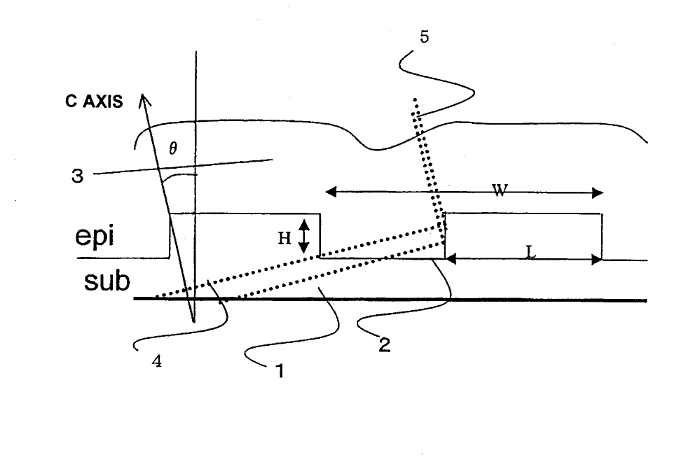

### CROSS REFERENCE TO RELATED APPLICATIONS

This application claims priority from Japanese application Serial No. 2007-159643, filed on Jun. 18, 2007. The disclosure of the priority application in its entirety, including the drawing, claims, and the specification thereof, is incorporated herein by reference.

### BACKGROUND OF THE INVENTION

A. Field of the Invention

This invention relates to a method of manufacturing a silicon carbide semiconductor substrate.

B. Description of the Related Art

Various measures are being taken to enhance the performance of semiconductor devices for power applications (hereafter “power devices”) using silicon semiconductor substrates (hereafter abbreviated “Si”), for the purpose of controlling large amounts of power. However, power devices are also used at high temperatures or in the presence of radiation, and in some cases Si power devices cannot be used under such conditions.

Also, in response to requests for still higher performance than Si power devices, the application of new semiconductor substrate materials is being studied. The silicon carbide semiconductor substrate addressed in this invention has a broad forbidden band width (for 4H-SiC, 3.26 eV; for 6H-SiC, 3.02 eV), and so control over electric conductivity at high temperature and radiation durability are excellent; also, because the dielectric breakdown voltage is approximately one order of magnitude higher than that for Si, application to high-withstand voltage devices with low turn-on resistance is possible. Also, SiC semiconductor substrates have an electron saturation drift velocity approximately twice that of Si semiconductor substrates, and so are also suited to control in high-frequency power applications. There exist various crystal forms (polytypes) of SiC crystal substrates, such as the above 4H-SiC and 6H-SiC; of these, 4H-SiC has excellent physical properties, and is promising as a semiconductor substrate material for power devices.

However, when using an SiC semiconductor substrate to manufacture a semiconductor device, ion implantation and impurity doping by thermal diffusion, which are normally indispensable process technologies for Si semiconductor devices, are difficult to perform; hence simultaneously with impurity doping control, epitaxial growth layers are formed in the required number of layers on the low-resistance SiC substrate (SUB), to manufacture an SiC semiconductor device having the desired semiconductor functions. However, such SiC semiconductor devices have the problem of frequent unsatisfactory characteristics, arising from crystal defects. In the following explanation, “SiC substrate” refers to a low-resistance SiC substrate, and “SiC semiconductor substrate” refers to an SiC substrate on which is formed an SiC epitaxial growth layer.

There is the following well-known technology relating to improvement of such SiC semiconductor devices, and in particular methods for SiC epitaxial growth resulting in low dislocation defect densities. For example, technology has been disclosed in which, by forming parallel grooves in an off-axis direction in a growth face inclined by 10 to 900 from the [0001] plane, so that growth planes are arranged at fixed intervals, and then performing epitaxial growth, and by repeating processes in which the grooves are filled with SiC crystals, so that crystal growth occurs at short intervals between single crystals, a silicon carbide semiconductor substrate can be manufactured with almost no dislocation crystal defects (see Japanese Patent Laid-open No. 2005-350278). Further, technology has been disclosed in which at least a portion of the semiconductor substrate has a plurality of undulations extending in one direction, and the second and subsequent epitaxial growth processes are performed after forming a plurality of undulations extending in one direction on at least a portion of the surface of a single-crystal layer formed immediately before, to obtain a single-crystal substrate with low crystal defect density (Japanese Patent Laid-open No. 2003-68654, corresponding to U.S. Pat. No. 6,736,894).

However, as is also described in the above references, numerous lattice defects and dislocations exist in SiC single crystals, and these impart adverse effects on the characteristics of SiC devices, so that improvement is sought. As such crystal defects, micropipes are representative of large defects in 4H-SiC. Micropipes are empty-core defects which penetrate in the c-axis direction, having a Burgers vector of 3 c or greater, and significantly lower the device withstand voltage. Technology has been reported for closing micropipes by means of epitaxial growth. However, this is because a micropipe which is a screw dislocation having a Burgers vector Nc (N≧3) is decomposed into screw dislocations having a Burgers vector of 2 c or less, and does not mean that the dislocations themselves are eliminated.

On the other hand, carrot-like defects are another kind of large defect. These are formed by the combination of screw dislocations and basal plane dislocations (hereafter abbreviated “BPDs”). It is reported that the defect density of these defects can also be reduced by SiC epitaxial growth at high temperatures.

Thus it has been found that by means of SiC epitaxial growth, large defects which clearly are a cause of degradation of electrical characteristics can be reduced.

However, when considering an SiC device for use as a semiconductor device, even when BPDs (basal plane dislocations) exist in the SiC semiconductor substrate, they may be the origin of stacking faults, resulting in fluctuations and scattering in the forward-direction voltage; and when carrot-like defects are formed, increases in leakage current may result. Hence both types of defects cause problems rendering devices unsatisfactory, and at present it cannot be stated that crystal defect problems in SiC devices have been resolved.

The present invention is directed to overcoming or at least reducing the effects of one or more of the problems set forth above.

### SUMMARY OF THE INVENTION

This invention was devised in light of the above situation, and its object is to provide a method of manufacturing silicon carbide semiconductor substrates in which the density of basal plane dislocations (BPDs) in particular is reduced in the SiC semiconductor substrate, and in which irregularities occurring in the surface of the SiC epitaxial layer due to this reduction can be flattened.

The direction of basal plane dislocations (BPDs) changes at the interface between the substrate and the epitaxial growth layer. As a result, it is known that, for example, a basal plane dislocation (BPD) may be converted into an edge dislocation (hereafter abbreviated “TED”). On the other hand, these inventors have found that by forming physical walls (trenches), as shown in the drawing, employing an aspect ratio which takes the off-axis angle into account, a trench aspect ratio configuration is possible such that conversion into TEDs is nearly 100% as a result of inevitable collisions of BPDs with the trench side walls during SiC epitaxial growth. By this means, basal plane dislocations (BPDs) are converted into edge dislocations (TEDs), and in particular when employed in a vertical-direction device, fluctuations in the forward-direction voltage can be alleviated, and the BPD defect density, which is related to the leakage current, can be greatly reduced, so that the product yield can be significantly improved. Further, after SiC epitaxial growth, irregularities arising from the trenches formed prior to SiC epitaxial growth occur in the surface of the SiC epitaxial growth layer, but by performing the high-temperature annealing of this invention, flattening is possible.

More specifically, according to the invention, in a method of manufacturing a silicon carbide semiconductor substrate in which, when forming a SiC epitaxial growth layer on an SiC substrate with an off-axis angle of 1° to 8°, prior to the SiC epitaxial growth, parallel line-shape irregularities, which have an irregularity cross-sectional aspect ratio equal to or greater than the tangent of the off-axis angle of the SiC substrate, are formed in the substrate surface, and the SiC epitaxial growth layer is then formed, the above object of the invention can be attained by setting the height of the irregularities between 0.25 μm and 5 μm.

According to a preferred embodiment, annealing is performed at a temperature of 1800° C. or higher after forming the SiC epitaxial growth layer.

According to another embodiment, it is preferable that the linear direction of parallel line-shape irregularities formed in the substrate surface be perpendicular to a direction of inclination of the off-axis angle of the SiC substrate.

By means of this invention, a method of manufacturing silicon carbide semiconductor substrates can be provided which reduces the density of basal plane dislocations (BPDs) in SiC semiconductor substrates, and which enables flattening of the irregularities occurring in the surface of the SiC epitaxial layer due to this reduction.

### BRIEF DESCRIPTION OF THE DRAWING

The foregoing advantages and features of the invention will become apparent upon reference to the following detailed description and the accompanying sole drawing FIGURE, which is a cross-sectional view of the silicon carbide semiconductor substrate of an embodiment of the invention.

### DETAILED DESCRIPTION OF SPECIFIC EMBODIMENTS

Below, silicon carbide semiconductor substrates and methods of manufacturing such substrates of this invention are explained in detail, referring to the drawings. This invention is not limited to the descriptions of the embodiments explained below, so long as the gist of the invention is not exceeded.

The sole drawing FIGURE shows a cross-sectional view of the SiC semiconductor substrate of Embodiment 1 of the invention. Below, experiments and an embodiment are explained in order to elucidate a method of manufacturing SiC semiconductor substrates of this invention.

### Embodiment 1

As the substrate prior to epitaxial growth (hereafter abbreviated to “SiC substrate” or “SUB”), an N (nitrogen)-doped n-type SiC substrate (10¹⁸ cm⁻³) 4-H SiC single crystal, subjected to mirror polishing and CMP treatment, was used; a face polished so as to be inclined by 80 from the (0001)_{Si} plane in the <11-20> direction was used.

Trenches 2 were formed on the surface of the SiC substrate by ICP (Inductive Coupled Plasma) etching in a straight line, in a direction perpendicular to the <11-20> direction of SiC substrate 1, using an oxide film as a mask. The drawing FIGURE shows a cross-sectional view of SiC substrate 1 with these trenches 2 formed. At this time, the trench depth H is set to 0.5 μm, the protruding portion width is set to 0.5 μm, and the trench interval (repetition pitch) W is set to 1.0 μm, such that basal plane dislocations (BPDs) 4 which grow always reach a trench side wall during SiC epitaxial growth. When basal plane dislocation (BPD) 4 reaches a trench side wall, the dislocation is converted into edge dislocation (TED) 5, as shown in the drawing. The mask is removed from SiC substrate 1 processed in this way, and after cleaning using an organic solvent and an acid, SiC substrate 1 is placed, with the Si face in which linear trenches 2 are formed facing upward, onto a graphite suscepter (not shown) coated with SiC crystals, in order to insert SiC substrate 1 into an epitaxial growth system (not shown). The suscepter with SiC substrate 1 placed thereupon is inserted into the center of a quartz tube in the SiC epitaxial growth system, and the pressure reduced to 1 Pa or lower. Next, vapor phase etching of the surface of SiC substrate 1 placed within the quartz tube is performed. Vapor phase etching is performed using a gas mixture in which hydrogen and hydrogen chloride are mixed at respective flow rates of 10 slm (standard liters/minute) and 3 sccm (standard cc/minute), at a pressure of 100 Torr (1 Torr=133.32 Pa), heating for 30 minutes at an ambient temperature of 1600° C. As the heating method used to reach an ambient temperature of 1600° C., RF coils placed on the periphery of the quartz tube may be used in RF inductive heating of the suscepter on which SiC substrate 1 is placed.

Next, SiC epitaxial growth layer 3 is formed on the surface of SiC substrate 1 on which linear trenches 2 have been formed. A gas mixture, the main components of which are hydrogen (H₂) at 10 slm, monosilane (SiH₄) at 3 sccm, propane (C₃H₈) at 2 sccm, and nitrogen at 1 slm, is introduced into the quartz tube. Heating is performed for one hour at 1500° C. and a pressure of 90 Torr (1 Torr=133.32 Pa). By this means, 4H-type SiC epitaxial growth layer 3 (nitrogen doping amount 10¹⁹ cm⁻³) of thickness approximately 10 μm is formed on SiC substrate 1. As a result, the density of large defects such as micropipes and carrot-type defects is reduced to 0.4/cm².

Next, in order to decrease the irregularities remaining in the surface of SiC epitaxial growth layer 1 formed on SiC semiconductor substrate 1, due to the linear trenches 2, high-temperature annealing is performed for 30 minutes at 1800° C. in a 3% SiH₄/Ar atmosphere. By this means the surface of the SiC semiconductor substrate is flattened, and the maximum step height is reduced from an initial 0.5 μm to 0.2 μm.

In order to evaluate the dislocation density in SiC epitaxial growth layer 3 thus grown, etching using potassium hydroxide (KOH) was performed. In this etching, a method was used in which the sample was immersed for 30 seconds in potassium hydroxide heated to 500° C. in a nickel (Ni) crucible. SEM (Scanning Electron Microscopy) observations were performed to count the defect density. The BPD density is approximately 3×10³ cm² when using a SiC semiconductor substrate on which irregularities are not formed, but upon measuring the dislocation density when using a SiC semiconductor substrate with irregularities formed the density was reduced by approximately 99%, to 3×10¹ cm².

If the off-axis angle of SiC substrate 1 is 0, the height of the irregularities is H, the width of the protruding portions is L, and the interval between irregularities (repetition pitch) is W, it was found that W-2H<Lx tan θ≦H is the condition for BPD 4 to always collide with a side wall of trench 2 in SiC substrate 1. Here, a smaller height H of the irregularities results in greater ease in flattening, and so is desirable. Hence from the above relation, it is necessary that W and L be made small. When patterning using an i-line stepper, the limits for W and L are 0.5 mm and 0.25 μm respectively. Hence given the above relation, in cases in which the off-axis angle is in the practical range from 1 to 80 due to cost considerations, the lower limit for H is 0.25 μm. On the other hand, the upper limit for H is determined by the limits up to which irregularities can be formed stably and flattening by high-temperature annealing is possible; 5 μm is thought to be reasonable. Because BPDs 4 propagate in directions parallel to the off-axis direction in normal epitaxially grown films, if the irregularities are provided perpendicular to the off-axis direction, the interval between irregularities W can be made the smallest, which is desirable.

By means of the embodiment of the invention described above, prior to SiC epitaxial growth, trenches of a prescribed size are formed in the surface of the SiC substrate perpendicular to the off-axis direction, after which the SiC epitaxial growth layer is formed, and by this means the BPD density can be decreased by 99% to 1%. Further, irregularities in the surface of the SiC epitaxial layer arising from the trenches can be reduced to a degree at which no practical problems arise in subsequent processes, in a flattening process in which a high-temperature annealing process is performed at 1800° C. or above after the SiC epitaxial growth.

Thus, a method of manufacturing a silicon carbide semiconductor substrate has been described according to the present invention. Many modifications and variations may be made to the techniques and structures described and illustrated herein without departing from the spirit and scope of the invention. Accordingly, it should be understood that the methods and apparatus described herein are illustrative only and are not limiting upon the scope of the invention.

What is claimed is:

1. A method of manufacturing a silicon carbide semiconductor substrate, comprising:
forming parallel line-shape irregularities in a surface of a silicon carbide substrate having an off-axis angle of 1° to 8°, said irregularities having a height between 0.25 μm and 5 μm and an irregularity cross-sectional aspect ratio equal to or greater than the tangent of the off-axis angle of said silicon carbide substrate; and then forming a silicon carbide epitaxial growth layer on said silicon carbide substrate.

2. The method of manufacturing a silicon carbide semiconductor substrate according to claim 1, wherein annealing is performed at a temperature of 1800° C. or higher after forming the silicon carbide epitaxial growth layer.

3. The method of manufacturing a silicon carbide semiconductor substrate according to claim 1, wherein the linear direction of parallel line-shape irregularities formed in the substrate surface is perpendicular to a direction of inclination of the off-axis angle of the silicon carbide substrate.

4. The method of manufacturing a silicon carbide semiconductor substrate according to claim 2, wherein the linear direction of parallel line-shape irregularities formed in the substrate surface is perpendicular to a direction of inclination of the off-axis angle of the silicon carbide substrate.

5. The method of manufacturing a silicon carbide semiconductor substrate according to claim 1, wherein W−2H≦L×tan θ≦H, where θ is the off-axis angle of the silicon carbide substrate, H is the height of the irregularities, L is the width of the irregularities, and W is the repetition pitch of the irregularities.
